(19) United States
(12) Patent Application Publication
(10) Pub. No.: US 2025/0393404 A1
(43) Pub. Date: Dec. 25, 2025

(54) DISPLAY PANEL, AN ELECTRONIC DEVICE INCLUDING THE SAME, AND METHOD OF MANUFACTURING THE DISPLAY PANEL

(71) Applicant: Samsung Display Co., Ltd., Yongin-si (KR)

(72) Inventor: HYUNEOK SHIN, Yongin-si (KR)

(21) Appl. No.: 19/089,876

(22) Filed: Mar. 25, 2025

(30) Foreign Application Priority Data
Jun. 20, 2024 (KR) 10-2024-0080492

(51) Int. Cl. H10K 59/122; H10K 59/12; H10K 59/35

(52) U.S. Cl. CPC H10K 59/122; H10K 59/1201; H10K 59/353

(57) ABSTRACT

A display panel includes a base layer including pixel areas and a non-pixel area adjacent to the pixel areas; light emitting elements each including a first electrode, a second electrode, and a light emitting stack between the first electrode and the second electrode and on the base layer; and a pixel definition layer having pixel openings defined therethrough to expose at least a portion of the first electrode and opening patterns defined therein to surround the pixel openings in a plan view, each of the open patterns including a first area and a second area having a width different from a width of the first area.

### CROSS-REFERENCE TO RELATED APPLICATION

The present application claims priority to and the benefit of Korean Patent Application No. 10-2024-0080492, filed on Jun. 20, 2024, in the Korean Intellectual Property Office, the entire disclosure of which is incorporated herein by reference.

### BACKGROUND

### 1. Field

Aspects of the present disclosure relate to a display panel and a method of manufacturing the same.

### 2. Description of Related Art

An electronic device, such as a smart phone, a tablet computer, a digital camera, a notebook computer, a navigation device, a television set, or the like, which provides a user with an image, includes a display panel to display the image.

The display panel includes red, green, and blue pixels to display colors, and a light emitting layer having the color of a corresponding pixel is formed in each pixel. In general, a light emitting layer is formed through a deposition method using a shadow mask, however, due to defects, such as, a sagging of the mask, etc., a process is developed in which the light emitting layer and other organic layers are commonly formed over the pixels through an open mask.

However, in the case where the organic layer is commonly formed, a lateral leakage current flows through the organic layer, which is commonly provided between adjacent pixels, resulting in color mixture and poor luminance.

The above information disclosed in this Background section is only for enhancement of understanding of the background of the invention and therefore it may contain information that does not form.

### SUMMARY

Aspects of embodiments of the present disclosure are directed to a display panel capable of preventing a lateral leakage current between pixels adjacent to each other, preventing a color mixture between the pixels adjacent to each other, and preventing luminance from being decreased, or substantially reduce the likelihood thereof.

Aspects of embodiments of the present disclosure are directed to a method of manufacturing the display panel.

According to some embodiments of the present disclosure, there is provided a display panel including: a base layer including pixel areas and a non-pixel area adjacent to the pixel areas; light emitting elements each including a first electrode, a second electrode, and a light emitting stack between the first electrode and the second electrode and on the base layer; and a pixel definition layer having pixel openings defined therethrough to expose at least a portion of the first electrode and opening patterns defined therein to surround the pixel openings in a plan view, each of the open patterns including a first area and a second area having a width different from a width of the first area.

In some embodiments, the pixel definition layer includes: a first definition layer having groove patterns defined therein and including an organic material; and a second definition layer on the first definition layer, and having the open patterns defined therein to overlap the groove patterns, and including an inorganic material.

In some embodiments, the organic material includes at least one of polyimide (PI), polystyrene (PS), or polyacrylate (PA), and the inorganic material includes at least one of silicon (Si) or silicon nitride (SiNx).

In some embodiments, in a plan view, a first width of the open pattern in the first area is greater than a second width of the open pattern in the second area.

In some embodiments, the first width is greater than or equal to about 0.3 micrometers and less than or equal to about 5 micrometers, and the second width is greater than or equal to about 0.05 micrometers and less than or equal to about 0.2 micrometers.

In some embodiments, the groove patterns overlapping the first area in a plan view have a first groove width greater than the first width, and the groove patterns overlapping the second area in a plan view have a second groove width greater than the second width.

In some embodiments, the second area includes a second-first area and a second-second area spaced apart from the second-first area and facing the second-first area in a plan view.

In some embodiments, the second area further includes a second-third area spaced apart from the second-first area and the second-second area.

In some embodiments, the second area further includes a second-fourth area spaced apart from the second-first area, the second-second area, and the second-third area and facing the second-third area in a plan view.

In some embodiments, the open patterns completely penetrate the second definition layer from an upper surface of the second definition layer to a lower surface of the second definition layer, each of the groove patterns is recessed in a direction toward the base layer, and a maximum depth of each of the groove patterns with respect to a plane extending from the upper surface of the first definition layer is less than a height of the first definition layer.

In some embodiments, a tip portion is protruded from a side surface of the second definition layer, which defines each of the open patterns, toward a center of the open patterns and is defined in the second definition layer.

In some embodiments, the light emitting element includes: a first light emitting stack; a first charge generation layer on the first light emitting stack; a second light emitting stack on the first charge generation layer; a second charge generation layer on the second light emitting stack; and a third light emitting stack on the second charge generation layer.

In some embodiments, each of the first, second, and third light emitting stacks includes a hole control layer, an electron control layer, and a light emitting layer between the hole control layer and the electron control layer, and wherein the hole control layer includes at least one of a hole injection layer and a hole transport layer, the hole transport layer includes at least one of a hole buffer layer and an electron block layer, and the electron control layer includes at least one of an electron injection layer and an electron transport layer.

In some embodiments, a pore is defined between each of the groove patterns and the light emitting stacks, at least a portion of the light emitting stacks and at least a portion of the charge generation layers are disconnected with respect to the pore to allow the pore to be positioned between disconnected portions of the light emitting stacks and the charge generation layers, and a residue including a same material as the light emitting stacks is in each of the groove patterns.

In some embodiments, the display panel further includes: light emitting stacks on the second definition layer; and charge generation layers between the light emitting stacks, wherein the second electrode on the light emitting stacks, and wherein at least one of the light emitting stacks and the charge generation layers is disconnected in the first and second areas, and the second electrode is disconnected in an area overlapping the first area and is not disconnected in an area overlapping the second area.

According to some embodiments of the present disclosure, there is provided a method of manufacturing a display panel, including: providing a preliminary display panel including a base layer including pixel areas and a non-pixel area adjacent to the pixel areas, a circuit element layer on the base layer and including insulating layers, and a first electrode on the circuit element layer; forming a first definition layer on the preliminary display panel; forming pixel openings through the first definition layer; forming a second definition layer on the first definition layer; forming open patterns in the second definition layer; forming groove patterns in the first definition layer to respectively overlap the open patterns; forming light emitting stacks on the second definition layer; and forming a second electrode on the light emitting stacks.

In some embodiments, each of the forming of the open patterns and the forming of the groove patterns includes a dry etching process.

In some embodiments, the forming of the groove patterns includes etching an upper surface of the first definition layer toward the base layer using a light passing through the open patterns.

In some embodiments, the forming of the open patterns includes forming a first portion having a first width and a second portion having a second width smaller than the first width in each of the open patterns, and the groove patterns overlapping the first portion have a first groove width greater than the first width, and the groove patterns overlapping the second portion have a second groove width greater than the second width.

In some embodiments, the method further includes: forming an encapsulation layer on the second electrode the encapsulation layer including a first inorganic encapsulation layer, an organic encapsulation layer on the first inorganic encapsulation layer, and a second inorganic encapsulation layer on the organic encapsulation layer.

According to some embodiments of the present disclosure, there is provided an electronic device including: a display panel configured to display an image; and a window on the display panel and including optically transparent material, wherein the display panel includes: a base layer including pixel areas and a non-pixel area adjacent to the pixel areas; light emitting elements each including a first electrode, a second electrode, and a light emitting stack between the first electrode and the second electrode and on the base layer; and a pixel definition layer having pixel openings defined therethrough to expose at least a portion of the first electrode and opening patterns defined therein to surround the pixel openings in a plan view, each of the open patterns comprising a first area and a second area having a width different from a width of the first area.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of an electronic device according to some embodiments of the present disclosure;

FIG. 2 is an exploded perspective view of an electronic device according to some embodiments of the present disclosure;

FIG. 3 is a cross-sectional view of a display module according to some embodiments of the present disclosure;

FIG. 4 is a cross-sectional view of a display panel according to some embodiments of the present disclosure;

FIG. 5 is an enlarged cross-sectional view of a portion of a light emitting element according to some embodiments of the present disclosure;

FIG. 6 is an enlarged plan view of the area AA′ of FIG. 2 according to some embodiments of the present disclosure;

FIG. 7 is an enlarged plan view of the area BB′ of FIG. 6 according to some embodiments of the present disclosure;

FIG. 8 is an enlarged cross-sectional view of a portion of a display panel taken along the line I-I′ of FIG. 7 according to some embodiments of the present disclosure;

FIGS. 9-10 are enlarged cross-sectional views of a portion of a display panel taken along the line II-II′ of FIG. 7 according to some embodiments of the present disclosure;

FIG. 11 is a flow diagram illustrating a method of manufacturing a display panel according to some embodiments of the present disclosure;

FIGS. 12A to 121 are views illustrating a method of manufacturing a display panel according to some embodiments of the present disclosure;

FIG. 13 is an enlarged plan view of a portion of a display panel according to some embodiments of the present disclosure;

FIG. 14 is an enlarged plan view of a portion of a display panel according to some embodiments of the present disclosure; and

FIG. 15 is an enlarged plan view of a portion of a display panel according to some embodiments of the present disclosure.

### DETAILED DESCRIPTION

The present disclosure may be variously modified and realized in many different forms, and thus specific embodiments will be exemplified in the drawings and described in further detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

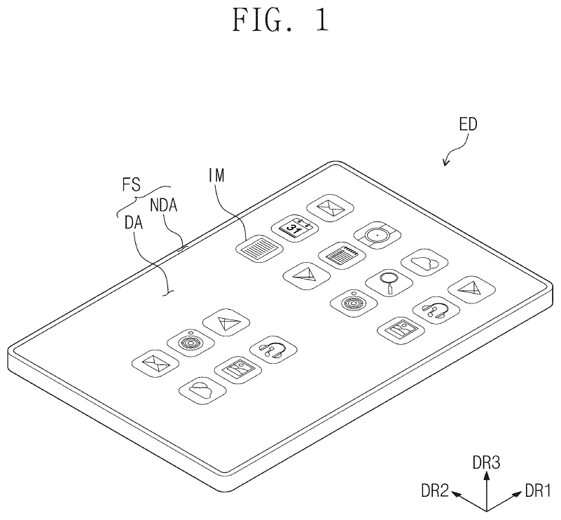

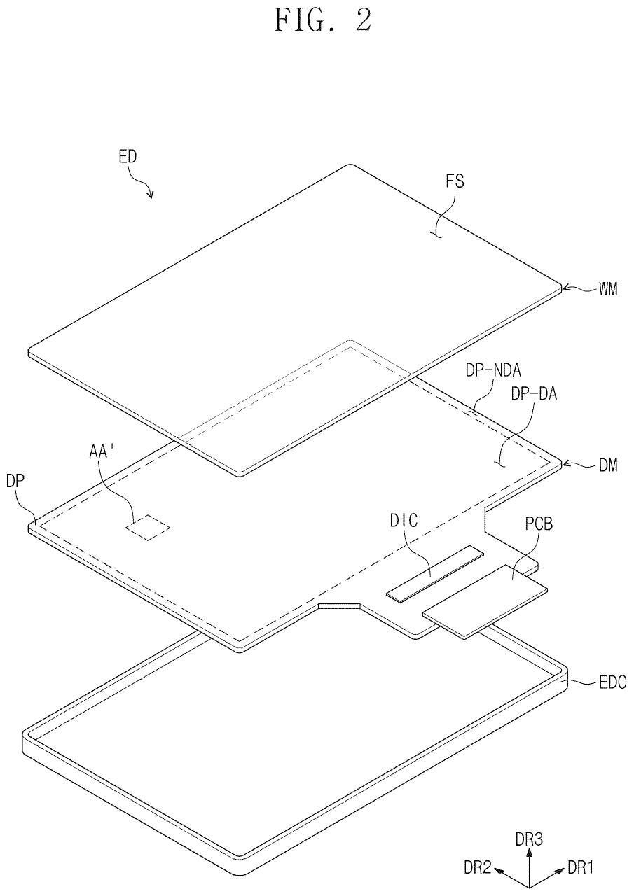

FIG. 1 is a perspective view of an electronic device ED according to some embodiments of the present disclosure. FIG. 2 is an exploded perspective view of the electronic device ED according to some embodiments of the present disclosure.

Referring to FIG. 1, the electronic device ED may be activated in response to electrical signals. The electronic device ED may display an image IM and may sense an external input. The electronic device ED may be implemented in various ways. For example, the electronic device ED may be a tablet computer, a notebook computer, a smartphone, a television set, or the like. In some embodiments, the tablet computer is shown as the electronic device ED, however, the present disclosure should not be limited thereto or thereby. The electronic device may be a smartphone or a large-sized display device, such as a notebook computer, a monitor, or a television set.

The electronic device ED may display the image IM through a display surface DS, which is substantially parallel to each of a first direction DR1 and a second direction DR2, toward a third direction DR3. The display surface DS through which the image IM is displayed may correspond to a front surface of the electronic device ED and a front surface FS of a window WM (e.g., refer to FIG. 2). Hereinafter, the display surface and the front surface of the electronic device ED and the front surface of the window WM (e.g., refer to FIG. 2) will be assigned with the same reference numeral. The image IM may include a still image as well as a video. FIG. 1 shows a plurality of application icons as a representative example of the image IM.

In some embodiments, front (or upper) and rear (or lower) surfaces of each member of the electronic device ED may be defined with respect to a direction in which the image IM is displayed. The front and rear surfaces may be opposite to each other in the third direction DR3, and a normal line direction of each of the front and rear surfaces may be substantially parallel to the third direction DR3. A separation distance in the third direction DR3 between the front surface and the rear surface may correspond to a thickness in the third direction DR3 of the electronic device ED. Directions indicated by the first, second, and third directions DR1, DR2, and DR3 may be relative to each other and may be changed to other directions. In the following descriptions, the expression “when viewed in a plane” or “in a plan view” may mean a state of being viewed on the plane defined by the first direction DR1 and the second direction DR2.

The electronic device ED may sense a user input applied thereto from the outside. The user input may include various types of external inputs, such as a part of the user's body, light, heat, or pressure. The user input may be provided in various ways, and the electronic device ED may sense the user input applied to a side or rear surface of the electronic device ED depending on its structure, however, the present disclosure should not be particularly limited.

As shown in FIG. 2, the electronic device ED may include the window WM, a display module DM, and an external case EDC. In some embodiments, the window WM may be coupled with the external case EDC to form an exterior of the electronic device ED. The external case EDC, the display module DM, and the window WM may be sequentially stacked in the third direction DR3.

The window WM may include an optically transparent material. The window WM may include an insulating panel. As an example, the window WM may include glass, plastic, or combination thereof.

As described above, the front surface FS of the window WM may define the front surface of the electronic device ED.

The window WM may include a bezel area and a transmissive area. The transmissive area may be an optically transparent area. For example, the transmissive area may have a transmittance of about 90% or more with respect to a visible light.

The bezel area may have a light transmittance relatively lower than that of the transmissive area. The bezel area may define a shape of the transmissive area. The bezel area may be defined adjacent to the transmissive area and may surround the transmissive area. The bezel area may have a set or predetermined color. The bezel area may overlap a non-display area DP-NDA of a display panel DP described in further detail later. The bezel area may cover the non-display area DP-NDA of the display panel DP to prevent the non-display area DP-NDA from being viewed from the outside, however, this is merely an example. According to some embodiments, the bezel area may be omitted from the window WM.

The display module DM may include at least the display panel DP. FIG. 2 shows only the display panel DP among components of the display module DM, however, the display module DM may further include a plurality of components disposed on and under the display panel DP. The detailed stack structure of the display module DM will be described in further detail later.

The display panel DP may include a display area DP-DA and the non-display area DP-NDA, which respectively correspond to a display area DA (e.g., refer to FIG. 1) and a non-display area NDA (e.g., refer to FIG. 1) of the electronic device ED. In the present disclosure, the expression “an area/portion corresponds to another area/portion” means that “an area/portion overlaps another area/portion”, however, the “areas and portions” should not be limited to having the same size as each other.

The display area DP-DA of the display panel DP may be an area in which the image IM (e.g., refer to FIG. 1) is displayed, and the non-display area DP-NDA may be an area in which a driving circuit, a driving line, and the like are disposed. Light emitting elements of pixels may be disposed in the display area DP-DA. The display area DP-DA may overlap at least a portion of the transmissive area of the window WM, and the non-display area DP-NDA may be covered by the bezel area of the window WM.

The display module DM may include a driving chip DIC disposed in the non-display area DP-NDA. The display module DM may further include a printed circuit board PCB coupled with the display panel DP in the non-display area DP-NDA. The printed circuit board PCB may be electrically connected to pads arranged in the non-display area DP-NDA of the display panel DP by an anisotropic adhesive layer.

The driving chip DIC may include driving elements to drive pixels of the display panel DP, e.g., a data driving circuit. FIG. 2 shows a structure in which the driving chip DIC is mounted on the display panel DP, however, the present disclosure should not be limited thereto or thereby. As an example, the driving chip DIC may be mounted on the printed circuit board PCB.

The external case EDC may accommodate the display module DM and may be coupled with the window WM. The external case EDC may protect components accommodated therein, such as the display module DM, from external impacts.

FIG. 3 is a cross-sectional view of the display module DM according to some embodiments of the present disclosure.

Referring to FIG. 3, the display module DM may include the display panel DP and an input sensing unit ISU. The display panel DP may have a configuration to generate the image IM (e.g., refer to FIG. 1). The image IM (e.g., refer to FIG. 1) generated by the display panel DP may be viewed from the outside by the user through the display area DA (e.g., refer to FIG. 1).

The display panel DP may be a light-emitting type display panel, however, it should not be particularly limited. For instance, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as a representative example of the display panel DP.

The input sensing unit ISU may be disposed on the display panel DP. The input sensing unit ISU may sense the external input applied thereto from the outside. The external input may include a variety of inputs provided from the outside of the electronic device ED (e.g., refer to FIG. 1). As an example, the external inputs may include a proximity input (e.g., hovering) applied when approaching close to or adjacent to the electronic device ED at a set or predetermined distance as well as a touch input by a part of the user's body (e.g., the user's hand). In addition, the external inputs may be provided in the form of force, pressure, light, etc., and it should not be particularly limited.

The input sensing unit ISU may be formed on the display panel DP through successive processes. In this case, the input sensing unit ISU may be disposed directly on the display panel DP. In the following descriptions, the expression “a component A is disposed directly on a component B.” means that no intervening elements are present between the component A and the component B. That is, a separate adhesive layer may not be disposed between the input sensing unit ISU and the display panel DP.

The display panel DP may include a base layer BL, a circuit element layer DP-CL disposed on the base layer BL, a display element layer DP-OLED disposed on the circuit element layer DP-CL, and an upper insulating layer TFL disposed on the display element layer DP-OLED.

The base layer BL may provide a base surface on which the circuit element layer DP-CL, the display element layer DP-OLED, and the upper insulating layer TFL are stacked. The base layer BL may be a rigid substrate or a flexible substrate that is bendable, foldable, or rollable. The base layer BL may be a glass substrate, a metal substrate, or a polymer substrate, however, it should not be limited thereto or thereby. According to some embodiments, the base layer BL may include an inorganic layer, an organic layer, or a composite material layer.

The base layer BL may have a multi-layer structure. For instance, the base layer BL may include a first synthetic resin layer, an inorganic layer having a single-layer or multi-layer structure, and a second synthetic resin layer disposed on the inorganic layer having a single-layer or multi-layer structure. Each of the first and second synthetic resin layers may include a polyimide-based resin, however, it should not be particularly limited.

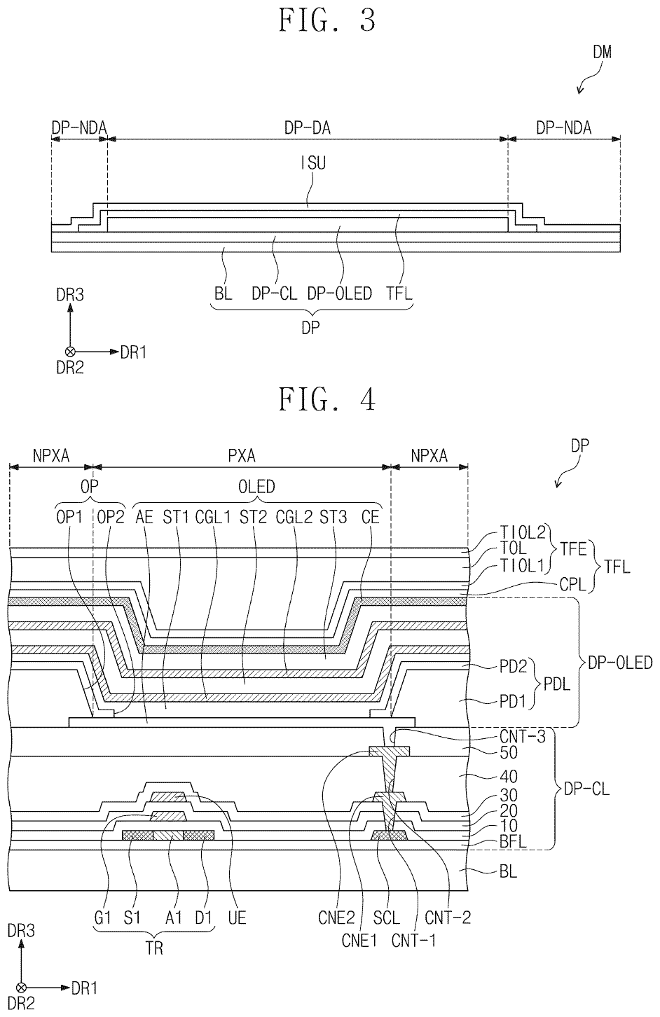

The base layer BL may include pixel areas PXA (e.g., refer to FIG. 4) and a non-pixel area NPXA (e.g., refer to FIG. 4) adjacent to the pixel areas PXA (e.g., refer to FIG. 4), and the pixel areas PXA (e.g., refer to FIG. 4) and the non-pixel area NPXA (e.g., refer to FIG. 4) will be described in further detail later. The circuit element layer DP-CL may be disposed on the base layer BL. The circuit element layer DP-CL may include a plurality of insulating layers, a plurality of conductive layers, and a semiconductor layer. The conductive layers of the circuit element layer DP-CL may form signal lines or a control circuit of the pixel.

The display element layer DP-OLED may be disposed on the circuit element layer DP-CL. The display element layer DP-OLED may include light emitting elements OLED (e.g., refer to FIG. 4). The display element layer DP-OLED may include, for example, organic light emitting elements, however, this is merely an example. The display element layer DP-OLED may include inorganic light emitting elements, organic-inorganic light emitting elements, or a liquid crystal layer.

The upper insulating layer TFL may be disposed on the display element layer DP-OLED and may protect the display element layer DP-OLED from moisture, oxygen, and foreign substances such as dust particles and the like. The upper insulating layer TFL may encapsulate the display element layer DP-OLED to prevent moisture and oxygen from entering the display element layer DP-OLED or substantially reducing the likelihood thereof. The upper insulating layer TFL may include at least one inorganic layer. The upper insulating layer TFL may include an organic layer and a plurality of inorganic layers encapsulating the organic layer. The upper insulating layer TFL may include a stack structure of inorganic layer/organic layer/inorganic layer.

The input sensing unit ISU may be disposed on the upper insulating layer TFL. The input sensing unit ISU may be formed on the upper insulating layer TFL through successive processes. The input sensing unit ISU may be disposed directly on the display panel DP. That is, a separate adhesive member may not be disposed between the input sensing unit ISU and the display panel DP. The input sensing unit ISU may be disposed to be in contact with the inorganic layer disposed at an uppermost position of the upper insulating layer TFL.

The display module DM may further include a protective member disposed on a lower surface of the display panel DP and an anti-reflective member disposed on an upper surface of the input sensing unit ISU. The anti-reflective member may reduce a reflectance of the display module DM with respect to the external light. The anti-reflective member may be disposed directly on the input sensing unit ISU through successive processes.

The anti-reflective member may include a light shielding pattern overlapping a reflective structure disposed under the anti-reflective member. The anti-reflective member may further include color filters. The color filters may be disposed between the light shielding pattern and may include a first color filter, a second color filter, and a third color filter, which correspond to a first color pixel, a second color pixel, and a third color pixel, respectively.

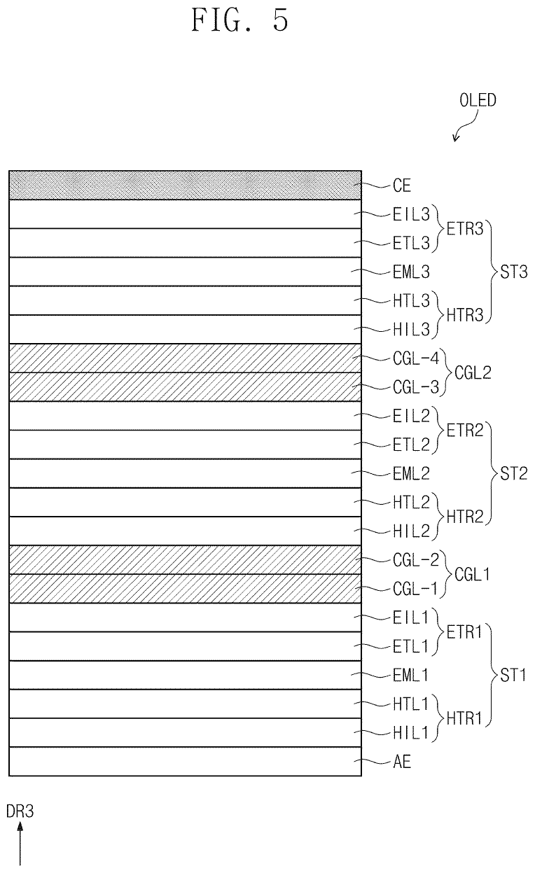

FIG. 4 is a cross-sectional view of the display panel DP according to some embodiments of the present disclosure. FIG. 5 is an enlarged cross-sectional view of a portion of the light emitting element OLED according to some embodiments of the present disclosure.

Hereinafter, the circuit element layer DP-CL, the display element layer DP-OLED, and the upper insulating layer TFL will be described with reference to FIGS. 4 and 5.

Referring to FIG. 4, the circuit element layer DP-CL may include at least one insulating layer and a circuit element. The circuit element may include a signal line and a pixel driving circuit. The circuit element layer DP-CL may be formed by a coating or depositing process to form an insulating layer, a semiconductor layer, and a conductive layer and a photolithography process to pattern the insulating layer, the semiconductor layer, and the conductive layer.

In some embodiments, the circuit element layer DP-CL may include a buffer layer BFL, first, second, third, fourth, and fifth insulating layers 10, 20, 30, 40, and 50, a transistor TR, connection electrodes CNE1 and CNE2, and a signal line SCL.

The buffer layer BFL may include a plurality of inorganic layers stacked one on another. A semiconductor pattern may be disposed on the buffer layer BFL. The buffer layer BFL may increase an adhesive force between the base layer BL and the semiconductor pattern.

The semiconductor pattern may include polysilicon, however, it should not be limited thereto or thereby. The semiconductor pattern may include an amorphous silicon or metal oxide. FIG. 4 shows a portion of the semiconductor pattern, and the semiconductor pattern may be further disposed in other areas of the pixel when viewed in the plane. The semiconductor pattern may be arranged according to a particular pattern over the pixels.

The semiconductor pattern may have different electrical properties depending on whether it is doped or not. The semiconductor pattern may include a first region A1 with low doping concentration and low conductivity and second regions S1 and D1 with relatively high doping concentration and high conductivity. One second region S1 may be disposed adjacent to one side of the first region A1, and the other second region S2 may be disposed adjacent to the other side of the first region A1. The second regions S1 and D1 may be doped with an N-type dopant or a P-type dopant. A P-type transistor may include a doped region doped with the P-type dopant. The first region A1 may be a non-doped region or may be doped at a concentration lower than the second regions S1 and D1.

The second regions S1 and D1 may substantially serve as an electrode or a signal line. The one second area S1 may correspond to a source of a transistor, and the other second area D1 may correspond to a drain of the transistor. FIG. 4 shows a portion of a signal line SCL formed of the semiconductor pattern. The signal line SCL may be connected to the drain of the transistor TR in a plan view.

The first insulating layer 10 may be disposed on the buffer layer BFL. The first insulating layer 10 may commonly overlap the pixels arranged in the display area DP-DA and may cover the semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon oxynitride, zirconium oxide, or hafnium oxide. Not only the first insulating layer 10 but also an insulating layer of the circuit element layer DP-CL described in further detail later may be an inorganic layer and/or an organic layer and may have a single-layer or multi-layer structure.

A gate G1 may be disposed on the first insulating layer 10. The gate G1 may be a portion of a metal pattern. The gate G1 may overlap the first region A1. The gate G1 may be used as a mask in a process of doping the semiconductor pattern.

The second insulating layer 20 may be disposed on the first insulating layer 10 and may cover the gate G1. The second insulating layer 20 may commonly overlap the pixels. An upper electrode UE may be disposed on the second insulating layer 20. The upper electrode UE may overlap the gate G1. The upper electrode UE may include a plurality of metal layers. According to some embodiments, the upper electrode UE may be omitted.

The third insulating layer 30 may be disposed on the second insulating layer 20 and may cover the upper electrode UE. A first connection electrode CNE1 may be disposed on the third insulating layer 30. The first connection electrode CNE1 may be connected to the signal line SCL via a contact hole CNT-1 defined through the first, second, and third insulating layers 10, 20, and 30.

The fourth insulating layer 40 may be disposed on the third insulating layer 30, and the fifth insulating layer 50 may be disposed on the fourth insulating layer 40. The fourth insulating layer 40 may be an organic layer. A second connection electrode CNE2 may be disposed on the fourth insulating layer 40. The second connection electrode CNE2 may be connected to the first connection electrode CNE1 via a contact hole CNT-2 defined through the fourth insulating layer 40.

The fifth insulating layer 50 may be disposed on the fourth insulating layer 40 and may cover the second connection electrode CNE2. The fifth insulating layer 50 may be an organic layer. The fifth insulating layer 50 may be a planarization layer.

The display element layer DP-OLED may include a pixel definition layer PDL and the light emitting element OLED.

The light emitting element OLED may be disposed on the fifth insulating layer 50. A first electrode AE may be disposed on the fifth insulating layer 50. The first electrode AE may be connected to the second connection electrode CNE2 via a contact hole CNT-3 defined through the fifth insulating layer 50.

The pixel definition layer PDL may be provided with (e.g., have or define) a pixel opening OP defined therethrough. The pixel opening OP may include a first pixel opening OP1 and a second pixel opening OP2. The first and second pixel openings OP1 and OP2 may be defined through first and second definition layers PD1 and PD2 described in further detail later, respectively.

At least a portion of the first electrode AE may be exposed through the pixel opening OP of the pixel definition layer PDL. The display area DP-DA may include the pixel area PXA and the non-pixel area NPXA adjacent to the pixel area PXA. The non-pixel area NPXA may surround the pixel area PXA.

In the some embodiments, the pixel definition layer PDL may include the first definition layer PD1 and the second definition layer PD2 disposed on the first definition layer PD1.

A portion of the second definition layer PD2 may be disposed on a side surface of the first definition layer PD1, which defines the first pixel opening OP1. A portion of the first electrode AE, which is exposed through the second pixel opening OP2, may be defined as the pixel area PXA.

The first definition layer PD1 may include an organic material. The first definition layer PD1 may be an organic layer. As an example, the first definition layer PD1 may include polyimide (PI), polystyrene (PS), or polyacrylate (PA).

The second definition layer PD2 may include an inorganic material. The second definition layer PD2 may be an inorganic layer. As an example, the second definition layer PD2 may include silicon (Si) or silicon nitride (SiNx).

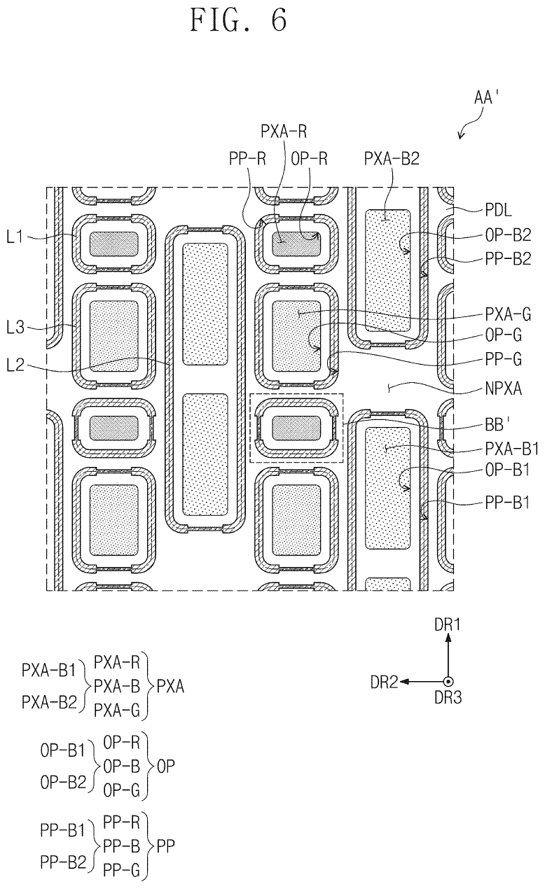

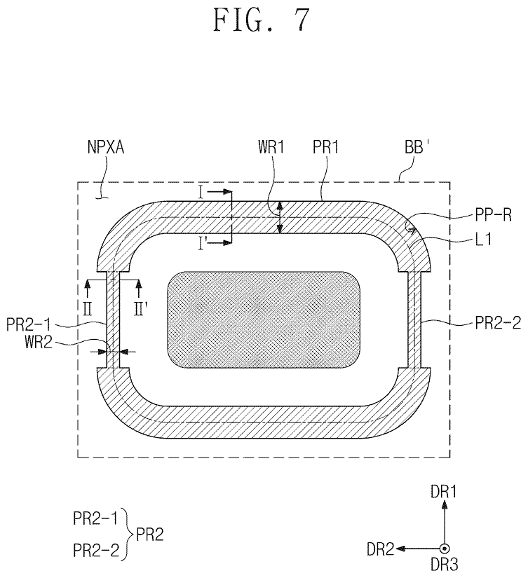

According to the display panel DP, open patterns PP (e.g., refer to FIG. 6) may be formed by etching the second definition layer PD2, and groove patterns GP (e.g., refer to FIG. 7) may be formed by etching the first definition layer PD1 using the open patterns PP (e.g., refer to FIG. 6) formed in the second definition layer PD2. Accordingly, a lateral leakage current may be reduced, and a second electrode CE may not be disconnected. The detailed structure of the pixel definition layer PDL and its effects will be described in further detail later.

Referring to FIG. 4, the light emitting element OLED may include the first electrode AE, a first light emitting stack ST1, a first charge generation layer CGL1, a second light emitting stack ST2, a second charge generation layer CGL2, a third light emitting stack ST3, and the second electrode CE, which are sequentially stacked. The light emitting element OLED may have a tandem structure in which the light emitting stacks ST1, ST2, and ST3 include light emitting layers EML1, EML2, and EML3 (e.g., refer to FIG. 5), respectively. Detailed structures of the light emitting element OLED will be described in further detail with reference to FIG. 5.

The upper insulating layer TFL may be disposed on the display element layer DP-OLED. In some embodiments, the upper insulating layer TFL may include a capping layer CPL and an encapsulation layer TFE disposed on the capping layer CPL.

The capping layer CPL may be disposed on the second electrode CE. The capping layer CPL may be in contact with the second electrode CE. The capping layer CPL may protect the second electrode CE. The capping layer CPL may include an organic material.

The encapsulation layer TFE may include a first inorganic encapsulation layer TIOL1, an organic encapsulation layer TOL disposed on the first inorganic encapsulation layer TIOL1, and a second inorganic encapsulation layer TIOL2 disposed on the organic encapsulation layer TOL. The first inorganic encapsulation layer TIOL1 and the second inorganic encapsulation layer TIOL2 may protect the display element layer DP-OLED from moisture and oxygen, and the organic encapsulation layer TOL may protect the display element layer DP-OLED from a foreign substance such as dust particles; however, the present disclosure should not be limited thereto or thereby. According to some embodiments, the encapsulation layer TFE may further include an organic layer or an inorganic layer.

The first light emitting stack ST1 may include a first light emitting layer EML1, a first hole control layer HTR1, and a first electron control layer ETR1 spaced apart from the first hole control layer HTR1 with the first light emitting layer EML1 interposed therebetween.

The first hole control layer HTR1 may include at least one of a first hole injection layer HIL1 and a first hole transport layer HTL1. The first hole transport layer HTL1 may include at least one of a first hole buffer layer and a first electron block layer.

The first electron control layer ETR1 may include at least one of a first electron injection layer EIL1 and a first electron transport layer ETL1. The first electron control layer ETR1 may include a first hole block layer.

The second light emitting stack ST2 may include a second light emitting layer EML2, a second hole control layer HRT2, and a second electron control layer ETR2 spaced apart from the second hole control layer HRT2 with the second light emitting layer EML2 interposed therebetween.

The second hole control layer HTR2 may include at least one of a second hole injection layer HIL2 and a second hole transport layer HTL2. The second electron control layer ETR2 may include at least one of a second electron injection layer EIL2 and a second electron transport layer ETL2. Descriptions of the first hole control layer HTR1 and the first electron control layer ETR1 may be equally applied to the second hole control layer HTR2 and the second electron control layer ETR2.

The third light emitting stack ST3 may include a third light emitting layer EML3, a third hole control layer HRT3, and a third electron control layer ETR3 spaced apart from the third hole control layer HRT3 with the third light emitting layer EML3 interposed therebetween. Descriptions of the first hole control layer HTR1 and the first electron control layer ETR1 may be equally applied to the third hole control layer HTR3 and the third electron control layer ETR3.

The light emitting stacks ST1, ST2, and ST3 may emit lights having the same wavelength as each other. As an example, the light emitted from each of the light emitting stacks ST1, ST2, and ST3 may be a blue light, however, the present disclosure should not be limited thereto or thereby. According to some embodiments, the lights emitted from the light emitting stacks ST1, ST2, and ST3 may have different wavelength ranges from each other. As an example, at least one of the light emitting stacks ST1, ST2, and ST3 may emit the blue light, another light emitting stack of the light emitting stacks ST1, ST2, and ST3 may emit a red light, and the other light emitting stack of the light emitting stacks ST1, ST2, and ST3 may emit a green light. The light emitting element OLED including the light emitting stacks ST1, ST2, and ST3 emitting the lights having different wavelength ranges from each other may emit a white light.

The charge generation layers CGL1 and CGL2 may be disposed between the light emitting stacks ST1 to ST3. When a voltage is applied to the charge generation layers CGL1 and CGL2, the charge generation layers CGL1 and CGL2 may form a complex through an oxidation-reduction reaction, and thus may generate charges (e.g., electrons and holes). In addition, the charge generation layers CGL1 and CGL2 may provide the generated charges to each of the light emitting stacks ST1, ST2, and ST3.

The charge generation layers CGL1 and CGL2 may double the efficiency of current generated in the light emitting stacks ST1, ST2, and ST3 and may adjust a balance of the charges between the light emitting stacks ST1, ST2, and ST3.

In some examples, the first charge generation layer CGL1 may have a layer structure in which a first lower charge generation layer CGL-1 and a first upper charge generation layer CGL-2 are attached to each other; however, it should not be limited thereto or thereby. According to some embodiments, a buffer layer may be further disposed between the first lower charge generation layer CGL-1 and the first upper charge generation layer CGL-2.

The first lower charge generation layer CGL-1 may be an n-type charge generation layer that is disposed adjacent to the first light emitting stack ST1 and provides electrons to the first light emitting stack ST1. The first lower charge generation layers CGL-1 may include an aryl amine-based organic compound.

The first upper charge generation layer CGL-2 may be a p-type charge generation layer that is disposed adjacent to the second light emitting stack ST2 and provides holes to the second light emitting stack ST2. The first upper charge generation layers CGL-1 may include a metal, an oxide of a metal, a carbide, a fluoride, or a mixture thereof.

The second charge generation layer CGL2 may have a layer structure in which a second lower charge generation layer CGL-3 and a second upper charge generation layer CGL4 are attached to each other. Descriptions of the first lower charge generation layer CGL-1 and the first upper charge generation layer CGL-2 may be equally applied to the second lower charge generation layer CGL-3 and the second upper charge generation layer CGL4.

According to some embodiments, the light emitting stacks ST1, ST2, and ST3 and the charge generation layers CGL1 and CGL2 may be commonly disposed over the pixels using an open mask, however, the present disclosure should not be limited thereto or thereby. According to some embodiments, at least one of the hole control layers HTR1, HTR2, and HTR3, the light emitting layers EML1, EML2, and EML3, and the electron control layers ETR1, ETR2, and ETR3 may be formed through a patterning process using a mask. As an example, each of the light emitting layers EML1, EML2, and EML3 may be disposed in an area corresponding to the pixel opening OP. That is, each of the light emitting layers EML1, EML2, and EML3 may be divided into several portions respectively disposed in the pixels.

The number of the light emitting stacks ST1, ST2, and ST3 and the number of the charge generation layers CGL1 and CGL2 should not be limited to those of FIG. 5. As an example, the light emitting element OLED may include two light emitting stacks and one charge generation layer disposed between the two light emitting stacks. According to some embodiments, the light emitting element OLED may include four or more light emitting stacks and three or more charge generation layers disposed between the four or more light emitting stacks.

The second electrode CE may be disposed on the third light emitting stack ST3. The second electrode CE may have a single integral shape and may be commonly disposed over the pixels. That is, the second electrode CE may be provided as a common layer.

In a display panel of the related art, light emitting stacks and charge generation layers, which serve as a “common layer,” transfer a current not only to a specific pixel but also to adjacent pixels. The current transferred between neighboring pixels may be defined as the lateral leakage current. In the present disclosure, the lateral leakage current may refer to a current that flows in a direction other than the third direction DR3, which is the stacking direction of the light emitting element OLED (e.g., refer to FIG. 4), that is, the direction in which the image IM (e.g., refer to FIG. 1) is displayed.

When the lateral leakage current is generated, a luminous efficiency is reduced, a color purity is degraded, and it may cause color mixture by slightly lighting up the other pixels.

In the display panel of the related art, disconnection of the light emitting stacks and the charge generation layers is induced to reduce the occurrence of the lateral leakage current, however, this sometimes leads to the disconnection of a second electrode, which is provided as a common layer to transmit a driving current. As a result, the reliability of the display panel may be deteriorated.

According to the display panel DP (e.g., refer to FIG. 2) of the present disclosure, a precise pattern may be formed by etching the second definition layer PD2, which is an inorganic layer, and the first definition layer PD1 is etched using the formed pattern, and thus, a structure with differential line width surrounding each pixel area PXA (e.g., refer to FIG. 5) may be formed. That is, as a line width of the pattern formed in the second definition layer PD2 is adjusted, a structure in which a depth of the pattern formed in the first definition layer PD1 is precisely adjusted. Accordingly, a structure in which the disconnection of the light emitting stacks and the charge generation layers is induced while stably connecting the second electrode CE is formed.

The differential line width structure according to the present disclosure will be described with reference to FIGS. 6 to 10.

FIG. 6 is an enlarged plan view of the area AA′ of FIG. 2 according to some embodiments of the present disclosure.

FIG. 6 shows an arrangement of the pixel areas PXA and the open patterns PP defined adjacent to the pixel areas PXA in the area AA′ of the display panel DP shown in FIG. 2.

Hereinafter, the lateral leakage current occurring between the pixels and the open patterns PP preventing or substantially reducing the likelihood of the occurrence of the lateral leakage current will be described with reference to FIG. 6.

Referring to FIG. 6, the pixel area PXA and the non-pixel area NPXA adjacent to the pixel area PXA may be defined in the display area DP-DA (e.g., refer to FIG. 2).

The pixel area PXA may include a first pixel area PXA-R, a second pixel area PXA-G, and a third pixel area PXA-B. The first, second, and third pixel areas PXA-R, PXA-G, and PXA-B may be distinguished from each other by the pixel definition layer PDL.

The first pixel area PXA-R, the second pixel area PXA-G, and the third pixel area PXA-B may display lights of different wavelengths. The first pixel area PXA-R may display a first light of a red wavelength, the second pixel area PXA-G may display a second light of a green wavelength, and the third pixel area PXA-B may display a third light of a blue wavelength.

The first pixel areas PXA-R may be alternately arranged with the second pixel areas PXA-G in the first direction DR1 to form a first pixel group. The third pixel areas PXA-B may be arranged in the first direction DR1 to form a second pixel group. In some embodiments, the second pixel group may include a plurality of sub-pixel groups, and each of the sub-pixel groups may include two third pixel areas PXA-B. The two third pixel areas PXA-B included in one sub-pixel group may be referred to as a third-first pixel area PXA-B1 and a third-second pixel area PXA-B2.

Each of the first pixel group including the first and second pixel areas PXA-R and PXA-G and the second pixel group including the third-first and third-second pixel areas PXA-B1 and PXA-B2 may be provided in plural form, and the first pixel groups may be alternately arranged with the second pixel groups in the second direction DR2.

First pixel openings OP-R respectively corresponding to the first pixel areas PXA-R, second pixel openings OP-G respectively corresponding to the second pixel areas PXA-G, and third pixel openings OP-B respectively corresponding to the third pixel areas PXA-B may be defined through the pixel definition layer PDL. In some embodiments, the third pixel openings OP-B may include third-first pixel openings OP-B1 respectively corresponding to the third-first pixel areas PXA-B1 and third-second pixel openings OP-B2 respectively corresponding to the third-second pixel areas PXA-B2.

The first, second, and third pixel areas PXA-R, PXA-G, and PXA-B may have different sizes from each other depending on wavelengths of the lights emitted therefrom. As an example, the third pixel area PXA-B emitting the third light may have the largest size, and the first pixel area PXA-R emitting the first light may have the smallest size, however, the present disclosure should not be limited thereto or thereby. According to some embodiments, the first, second, and third pixel areas PXA-R, PXA-G, and PXA-B may have the same or substantially the same size as each other, or the first, second, and third pixel areas PXA-R, PXA-G, and PXA-B may be defined with an area ratio different from that shown in FIG. 6.

According to some embodiments, the first, second, and third pixel areas PXA-R, PXA-G, and PXA-B may emit lights of other colors other than the red wavelength light, and the green wavelength light, and the blue wavelength light.

In some embodiments, the first pixel area PXA-R may have a rectangular shape defined by long sides extending in the second direction DR2 and short sides extending in the first direction DR1 and provided with (e.g., have) rounded corners each where the long side and the short side adjacent to the long side are connected. Each of the second pixel area PXA-G and the third pixel area PXA-B may have a rectangular shape defined by long sides extending in the first direction DR1 and short sides extending in the second direction DR2 and provided with (e.g., have) rounded corners each where the long side and the short side adjacent to the long side are connected.

The non-pixel area NPXA may correspond to areas between the pixel areas PXA-R, PXA-G, and PXA-B adjacent to each other and may correspond to the pixel definition layer PDL.

Referring to FIG. 6, first, second, and third imaginary lines L1, L2, and L3 may be defined in the pixel definition layer PDL. The first, second, and third imaginary lines L1, L2, and L3 may be defined in the non-pixel area NPXA. When viewed in the plane, the first, second, and third imaginary lines L1, L2, and L3 may be imaginary lines surrounding the first, second, and third pixel openings OP-R, OP-G, OP-B1, and OP-B2. The first, second, and third pixel openings OP-R, OP-G, OP-B1, and OP-B2 may be completely enclosed by the first, second, and third imaginary lines L1, L2, and L3. The first, second, and third imaginary lines L1, L2, and L3 may serve as auxiliary lines to pattern the pixel definition layer PDL.

The open patterns PP may be openings penetrating through the second definition layer PD2 included in the pixel definition layer PDL in the thickness direction. FIG. 6 shows the open patterns PP that surround each of the pixel areas PXA and have differential line widths as a representative example. The open patterns PP may be formed along the first, second, and third imaginary lines L1, L2, and L3. The open patterns PP may overlap the first, second, and third imaginary lines L1, L2, and L3.

The open patterns PP may include a first open pattern PP-R, a second open pattern PP-G, and a third open pattern PP-B. The third open pattern PP-B may include a third-first open pattern PP-B1 and a third-second open pattern PP-B2.

FIG. 7 is an enlarged plan view of the area BB′ of FIG. 6 according to some embodiments of the present disclosure.

FIG. 7 is an enlarged plan view illustrating the first open pattern PP-R. Descriptions of the first open pattern PP-R with reference to FIGS. 7 to 9 may be applied to the second open pattern PP-G (e.g., refer to FIG. 6) and the third open pattern PP-B in the same or similar manner.

Hereinafter, a shape of the first open pattern PP-R in the plane will be described with reference to FIG. 7.

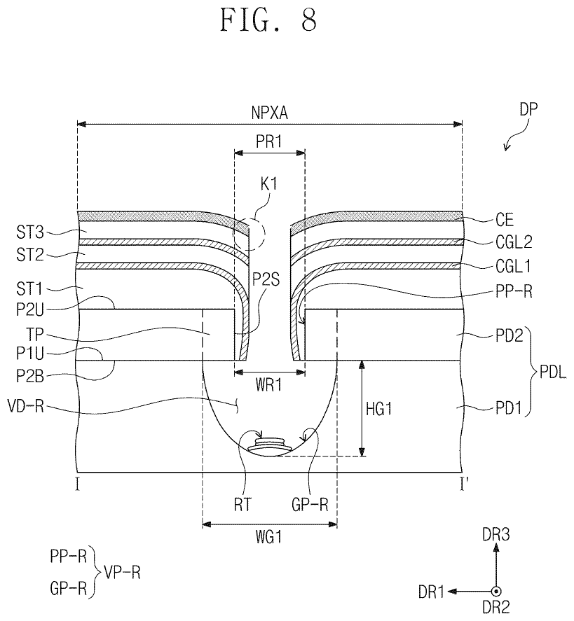

The first open pattern PP-R may overlap the first imaginary line L1 and may completely surround the first pixel area PXA-R (e.g., refer to FIG. 6). The first open pattern PP-R may correspond to an opening completely penetrating through the second definition layer PD2 (e.g., refer to FIG. 8) in the thickness direction, and this will be described later.

For the convenience of explanation, areas of the first open pattern PP-R are defined as follows. The first open pattern PP-R may include a first area PR1 and a second area PR2. The second area PR2 may include a second-first area PR2-1 and a second-second area PR2-2.

FIG. 7 shows a structure in which the second-first area PR2-1 and the second-second area PR2-2 are respectively positioned at a center of each side forming the first imaginary line L1 as a representative example, however, the position of the second area PR2 may be changed by taking into account the shape of the pixel area PXA (e.g., refer to FIG. 6).

When viewed in the plane, a width of the first open pattern PP-R in the first area PR1 may be referred to as a first width WR1, and a width of the first open pattern PP-R in the second area PR2 may be referred to as a second width WR2. The width of the first open pattern PP-R in the first area PR1 may be different from the width of the first open pattern PP-R in the second area PR2. That is, the first width WR1 may be different from the second width WR2. The first open pattern PP-R may have the differential line width structure.

The second width WR2 may be smaller than the first width WR1. As an example, the second width WR2 may be equal to or greater than about 0.3 μm and equal to or smaller than about 5 μm, and the first width WR1 may be equal to or greater than about 0.05 μm and equal to or smaller than about 0.2 μm.

The first open pattern PP-R may disconnect at least a portion of the light emitting stacks ST1 to ST3 (e.g., refer to FIG. 4) and the charge generation layers CGL1 and CGL2 (e.g., refer to FIG. 4) in the first area PR1 and the second area PR2. Accordingly, the lateral leakage current of the display panel DP may be prevented from occurring or the likelihood thereof may be substantially reduced, the luminance may be prevented from being deteriorated or the likelihood thereof may be substantially reduced, and the display efficiency may be improved (e.g., increased). In addition, the color mixture between the pixels adjacent to each other may be prevented, and thus, the display quality may be improved (e.g., increased).

In addition, the first open pattern PP-R may allow the second electrode CE (e.g., refer to FIG. 4) to be electrically continuous in the second area PR2. Therefore, the second electrode CE (e.g., refer to FIG. 4) provided as the common layer may stably transmit the driving voltage.

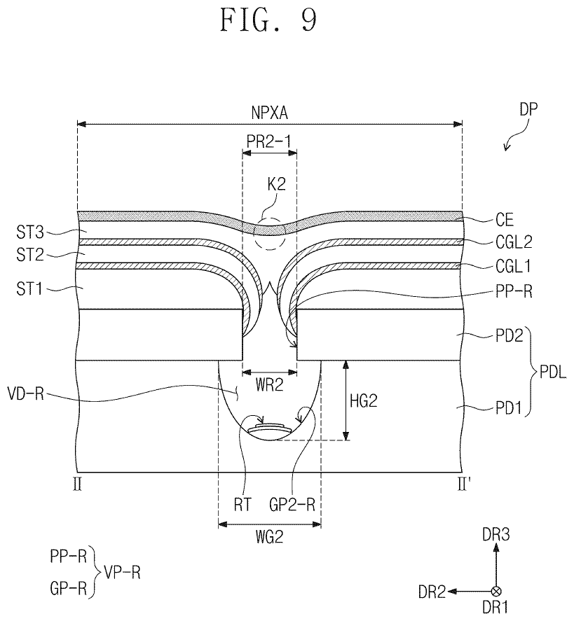

FIG. 8 is an enlarged cross-sectional view of a portion of the display panel DP taken along the line I-I′ of FIG. 7 according to some embodiments of the present disclosure. FIG. 9 is an enlarged cross-sectional view of a portion of the display panel DP taken along the line II-II′ of FIG. 7 according to some embodiments of the present disclosure.

Hereinafter, a cross-section structure of a first valley pattern VP-R in the first area PR1 and the second-first area PR2-1 will be described with reference to FIGS. 8 and 9. Descriptions of the first valley pattern VP-R with reference to FIGS. 8 and 9 may be applied to a second valley pattern including the second open pattern PP-G (e.g., refer to FIG. 6) and a second groove pattern and a third valley pattern including the third open pattern PP-B (e.g., refer to FIG. 6) and a third groove pattern.

The first valley pattern VP-R may include a first groove pattern GP-R and the first open pattern PP-R. The first valley pattern VP-R may allow the light emitting stacks ST1, ST2, and ST3, the charge generation layers CGL1 and CGL2, and the second electrode CE to be disconnected in the first area PR1.

The first open pattern PP-R may be defined penetrating through the second definition layer PD2 from an upper surface P2U of the second definition layer PD2 to a lower surface P2B of the second definition layer PD2. The first open pattern PP-R may penetrate through the second definition layer PD2 in the third direction DR3. The first open pattern PP-R may be formed by a dry etching process, and this will be described in further detail below.

A tip portion TP protruded from a side surface P2S of the second definition layer PD2, which defines the first open pattern PP-R, toward a center of the first open pattern PP-R may be defined in the second definition layer PD2.

The first groove pattern GP-R may be obtained by recessing an upper surface P1U of the first definition layer PD1 in the thickness direction. That is, the first groove pattern GP-R may be obtained by recessing the upper surface P1U of the first definition layer PD1 in a direction parallel to the third direction DR3. The first groove pattern GP-R may be obtained by recessing the upper surface P1U of the first definition layer PD1 along a direction toward the base layer BL (e.g., refer to FIG. 4).

The first groove pattern GP-R may overlap the first open pattern PP-R. The first groove pattern GP-R may be dry-etched by gas or light passing through the first open pattern PP-R. The first groove pattern GP-R may have a first groove width WG1 and a first groove depth HG1, which are determined by the first width WR1 of the first open pattern PP-R.

As an example, when the etching process of the first definition layer PD1 is performed as “isotropic etching”, at least a portion of the first definition layer PD1 overlapping the tip portion TP may be etched. Accordingly, the first definition layer PD1 may have an undercut shape as shown in FIG. 8.

The first groove pattern GP-R may have the first groove width WG1. When viewed in a cross-section, the first groove width WG1 may correspond to a maximum width in the second direction DR2 of the first groove pattern GP-R. The first groove width WG1 may be greater than the first width WR1.

However, the present disclosure should not be limited thereto or thereby. As an example, when the etching process of the first definition layer PD1 is performed as “anisotropic etching”, the portion of the first definition layer PD1, which overlaps the tip portion TP, may not be etched. In this case, the first groove width WG1 may be substantially the same as the first width WR1.

A maximum depth of the first groove pattern GP-R with respect to a plane extending from the upper surface of the first definition layer PD1 may be defined as the first groove depth HG1. The first groove depth HG1 may be less than a height of the first definition layer PD1. That is, the first groove pattern GP-R may not completely penetrate the first definition layer PD1.

A first pore VD-R may be defined as an inner space of the first valley pattern VP-R. That is, the first pore VD-R may be defined as an inner space of the first groove pattern GP-R and the first open pattern PP-R. The first pore VD-R may be positioned under a plane obtained by extending the upper surface of the second definition layer PD2.

In the first area PR1, the second electrode CE, the light emitting stacks ST1 to ST3, and the charge generation layers CGL1 and CGL2 may be disconnected. The second electrode CE, the light emitting stacks ST1 to ST3, and the charge generation layers CGL1 and CGL2 may be disconnected, and the first pore VD-R may be disposed in the disconnected portion of the second electrode CE, the light emitting stacks ST1 to ST3, and the charge generation layers CGL1 and CGL2. As shown in an area K1 of FIG. 8, the second electrode CE may be disconnected in the first area PR1.

A residue RT may be disposed in the first valley pattern VP-R. The residue RT disposed in the first groove pattern GP-R may include substantially the same material as the light emitting stacks ST1 to ST3. The residue RT may correspond to a material used to form the first to third light emitting stacks ST1 to ST3 and the charge generation layers CGL1 and CGL2 and accumulated inside the first groove pattern GP-R during the formation process of the first to third light emitting stacks ST1 to ST3 and the charge generation layers CGL1 and CGL2.

Referring to FIG. 9, the second width WR2 in the second-first area PR2-1 corresponding to the first open pattern PP-R may be smaller than the first width WR1 (e.g., refer to FIG. 8). Accordingly, the upper surface P1U of the first definition layer PD1 may be etched relatively less compared to that in the first area PR1 (e.g., refer to FIG. 8) in the process of etching the first definition layer PD1.

Accordingly, the second groove pattern GP2-R may have a shape that is less recessed than the first groove pattern GP-R (e.g., refer to FIG. 8). That is, a second groove width WG2 may be smaller than the first groove width WG1 (e.g., refer to FIG. 8). A second groove depth HG2 may be smaller than the first groove depth HG1 (e.g., refer to FIG. 8). That is, according to the display panel DP (e.g., refer to FIG. 3), the degree of etching of the first definition layer PD1 may also be precisely controlled by changing the shape or width of the first open pattern PP-R formed on the second definition layer PD2.

A portion of the first pore VD-R, which overlaps the second-first area PR2-1, may be smaller than a portion of the first pore VD-R, which overlaps the first area PR1 (e.g., refer to FIG. 8). Therefore, some of the light emitting stacks ST1 to ST3 and the charge generation layers CGL1 and CGL2 may be disconnected, and the others may be continuously formed without being disconnected.

However, because the second electrode CE is disposed above the light emitting stacks ST1 to ST3 and the charge generation layers CGL1 and CGL2, the second electrode CE may have a completely continuous shape when some of the light emitting stacks ST1 to ST3 and the charge generation layers CGL1 and CGL2 are continuously formed. Accordingly, the second electrode CE may not be disconnected in the second-first area PR2-1 and may effectively transmit the driving voltage.

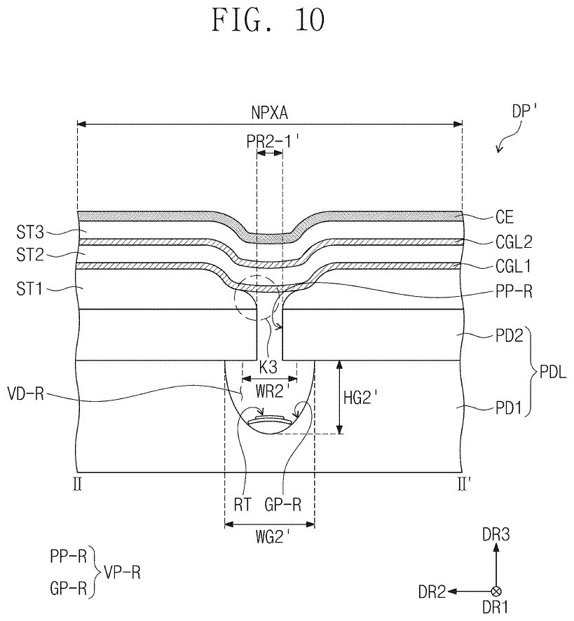

FIG. 10 is an enlarged cross-sectional view of a display panel DP′ in a second-first area PR2-1′ according to some embodiments of the present disclosure. FIG. 10 shows a first open pattern PP-R having a second width WR2′ smaller than the second width WR2 described with reference to FIG. 9.

When compared to the display panel DP described with reference to FIG. 9, a second charge generation layer CGL2, a second light emitting stack ST2, and a first charge generation layer CGL1 may also be continuous without being disconnected. However, because a first light emitting stack ST1 is still disconnected, a continuity of a hole injection layer of the first light emitting stack ST1 may be blocked, and thus, at least a portion of the lateral leakage current may be reduced or prevented.

As described above, the shape of the first definition layer may be precisely adjusted by changing the shape of the open pattern, and thus, the shape of the valley pattern and the inner space of the valley pattern may be controlled. Accordingly, it is possible to secure an electrical connectivity of the second electrode while blocking the lateral leakage current.

According to the display panel, the second electrode CE may be disconnected in the first area PR1 and may not be disconnected in the second area PR2 (e.g., refer to FIG. 7), and thus, the driving voltage may be transmitted. In addition, at least some of the light emitting stacks ST1 to ST3 and the charge generation layers CGL1 and CGL2 may be disconnected in the first area PR1 and the second area PR2 (e.g., refer to FIG. 7), the lateral leakage current may be reduced. Therefore, the luminance of the display panel may increase, and the color mixture may be prevented from occurring.

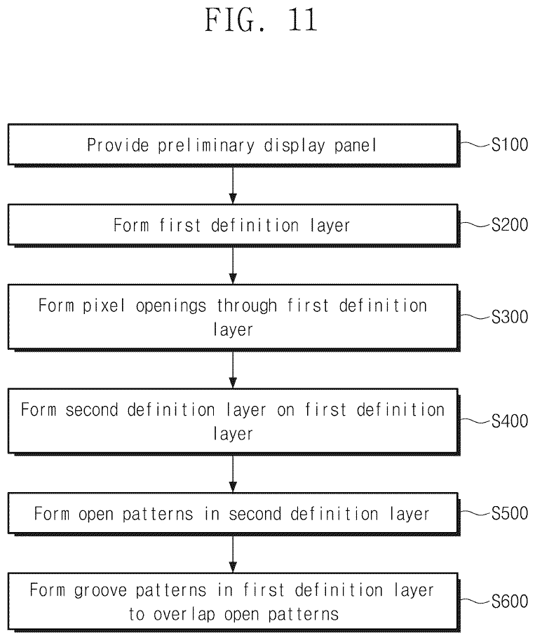

FIG. 11 is a flow diagram illustrating a method of manufacturing the display panel according to some embodiments of the present disclosure.

The manufacturing method of the display panel may include providing a preliminary display panel including the base layer including the pixel areas and the non-pixel area adjacent to the pixel areas, the circuit element layer disposed on the base layer and including the insulating layers, and the first electrode disposed on the circuit element layer (S100), forming the first definition layer on the preliminary display panel (S200), forming the pixel openings through the first definition layer (S300), forming the second definition layer on the first definition layer (S400), forming the open patterns in the second definition layer (S500), and forming the groove patterns in the first definition layer to respectively overlap the open patterns (S600).

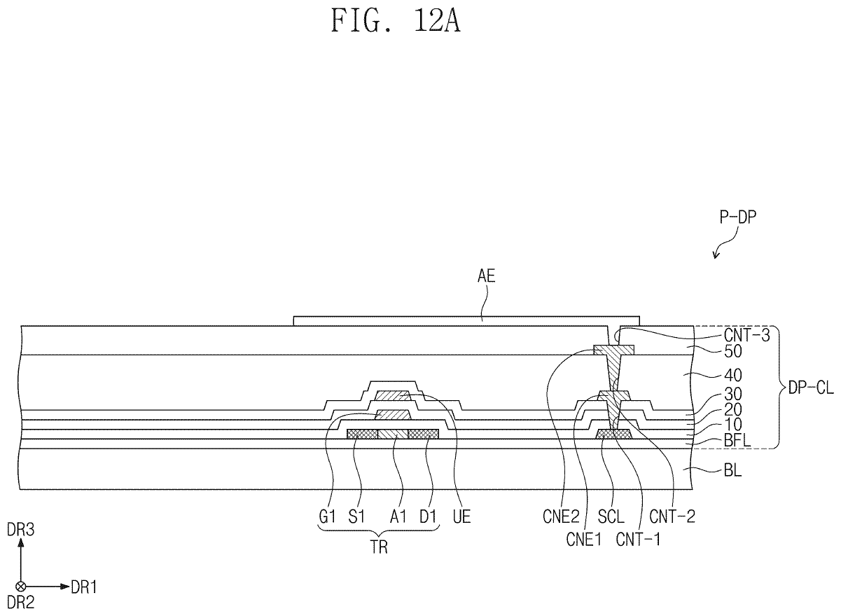

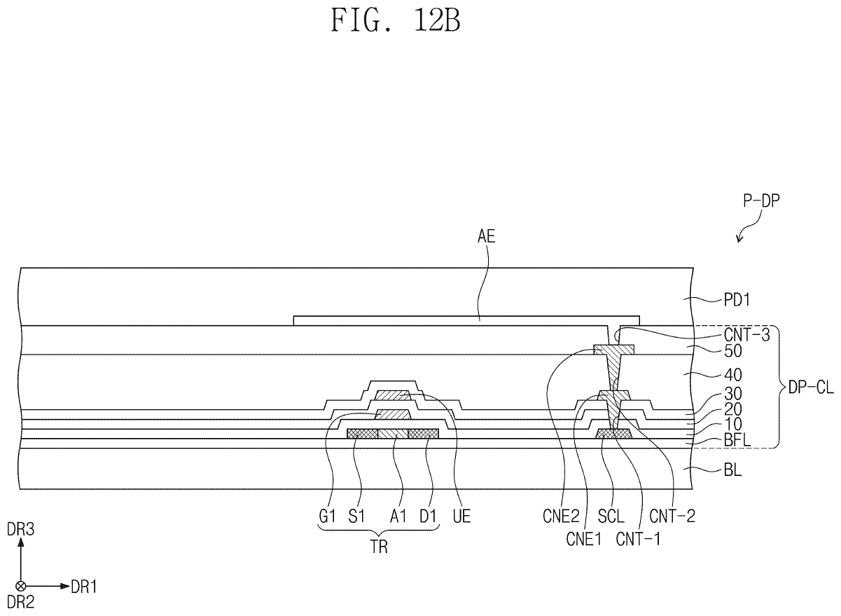

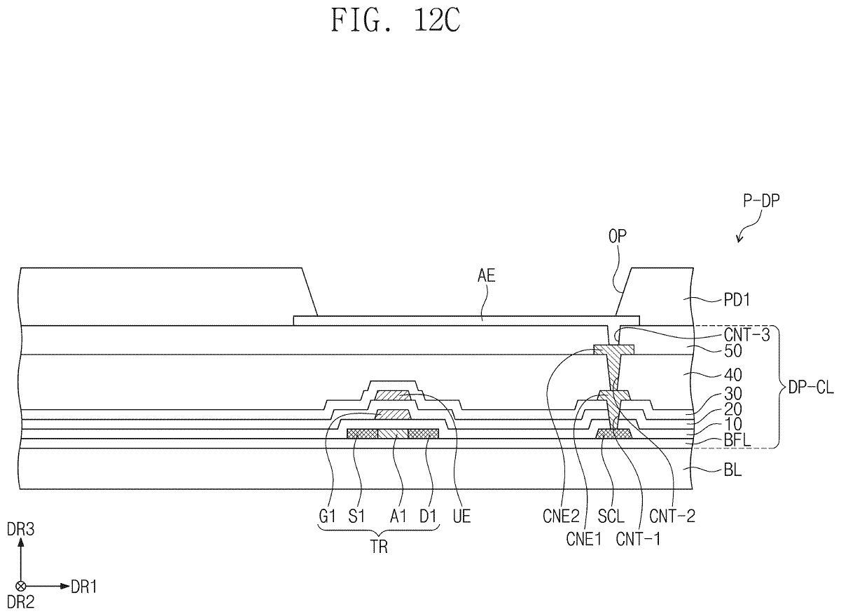

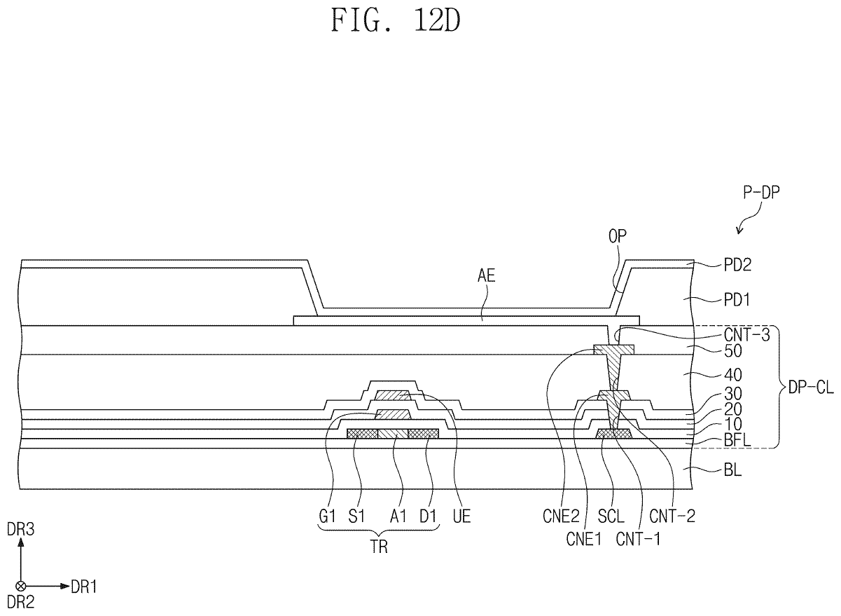

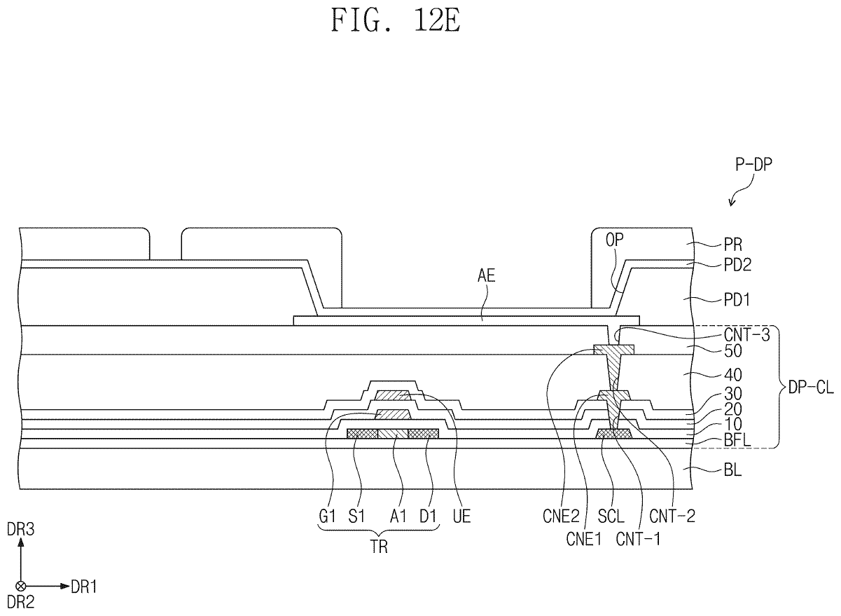

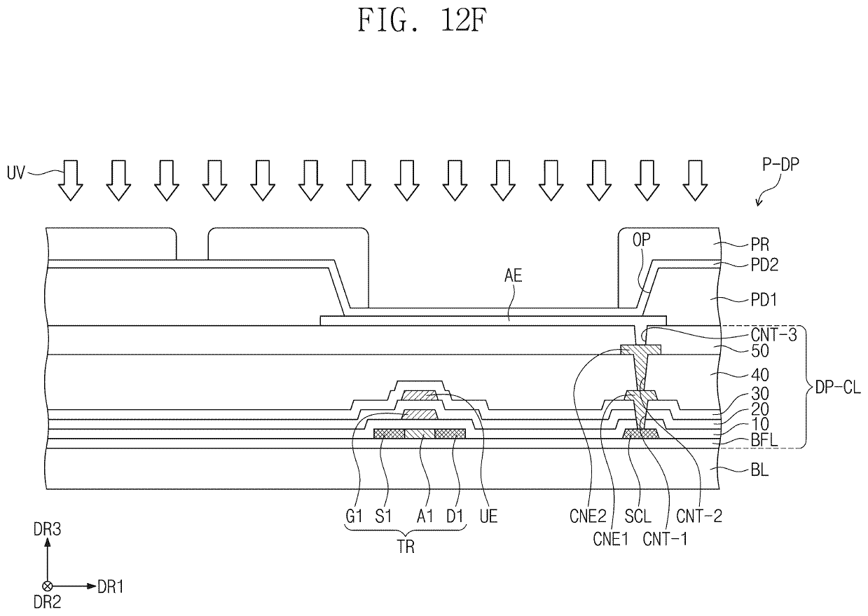

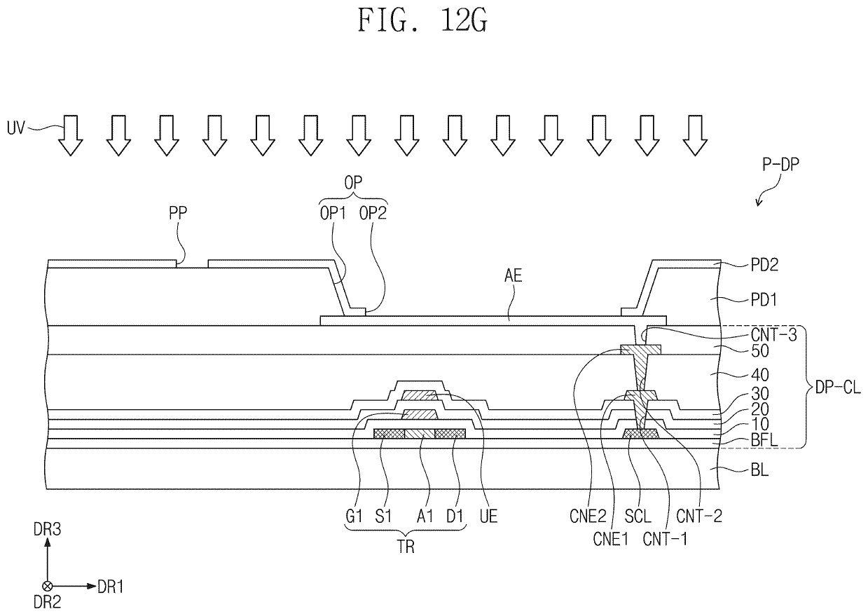

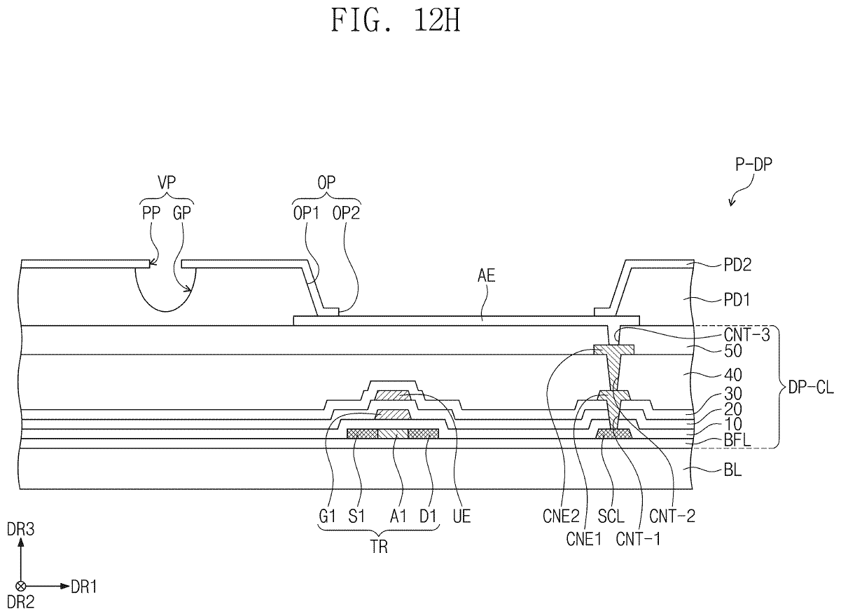

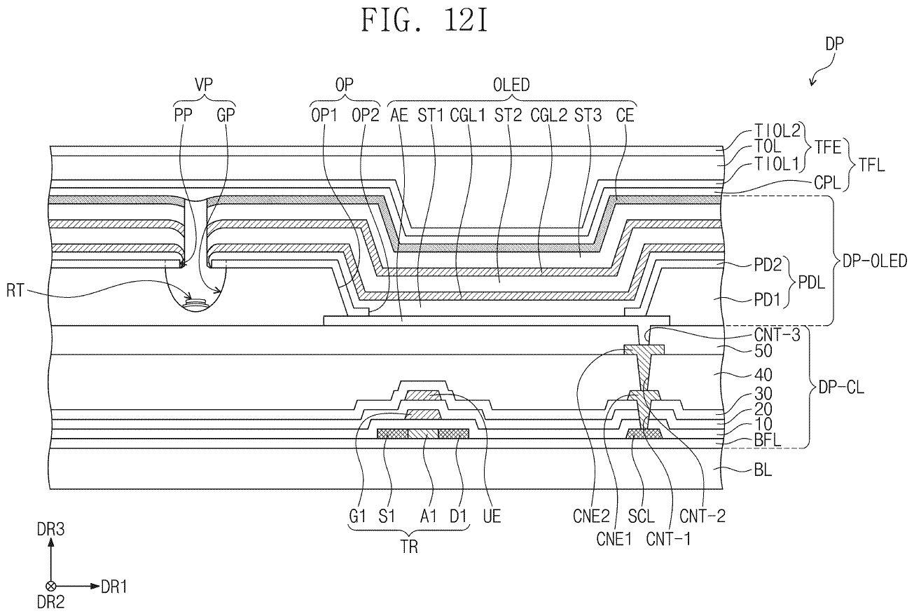

FIGS. 12A to 121 are views illustrating a method of manufacturing the display panel according to some embodiments of the present disclosure. In FIGS. 12A to 121, the same/similar reference numerals denote the same/similar elements in FIGS. 1 to 10, and thus, detailed descriptions of the same/similar elements may not be repeated.

Referring to FIG. 12A, the preliminary display panel P-DP including the base layer BL, the circuit element layer DP-CL disposed on the base layer BL and including the insulating layers, and the first electrode AE disposed on the circuit element layer DP-CL may be provided.

Referring to FIG. 12B, the first definition layer PD1 may be disposed on the preliminary display panel P-DP. The first definition layer PD1 may include the organic material. As an example, the first definition layer PD1 may include polyimide (PI), polystyrene (PS), polyacrylate (PA), and/or the like. The forming of the first definition layer PD1 may include forming a photoresist.

Referring to FIG. 12C, the pixel opening OP may be formed through the first definition layer PD1. The pixel opening OP may be formed to overlap the first electrode AE. At least the portion of the first electrode AE may be exposed through the pixel opening OP.

Referring to FIG. 12D, the second definition layer PD2 may be formed on the first definition layer PD1.

The second definition layer PD2 may include the inorganic material. As an example, the second definition layer PD2 may include silicon (Si) or silicon nitride (SiNx). The forming of the second definition layer PD2 may be performed by a chemical vapor deposition (CVD) process.

Referring to FIGS. 12E and 12F, the open patterns PP (e.g., refer to FIG. 12G) may be formed in the second definition layer PD2. The forming of the open patterns PP may be performed by placing a photoresist PR on the second definition layer PD2 and irradiating plasma or light to etch the second definition layer PD2 through an open area of the photoresist PR. The etching of the second definition layer PD2 may be performed by the dry etching process.

Therefore, the open pattern PP (e.g., refer to FIG. 12G) through which the portion of the upper surface of the first definition layer PD1 is exposed may be formed. In this case, the upper surface of the first definition layer PD1, which is exposed through the open pattern PP (e.g., refer to FIG. 12G), may be a portion in which the groove patterns GP (e.g., refer to FIG. 12H) are formed.

In addition, the second pixel opening OP2 may be formed to expose the portion of the first electrode AE. The light emitting stacks ST1, ST2, and ST3 (e.g., refer to FIG. 12I) may be stacked on the first electrode AE. Portions of the light emitting stacks ST1, ST2, and ST3 (e.g., refer to FIG. 12I) may be disposed inside the second pixel opening OP2.

Referring to FIG. 12G, the groove patterns GP may be formed in the first definition layer PD1 to overlap the open patterns PP.

That is, a dry etching process may be performed using the open patterns PP formed in the second definition layer PD2 to form the groove pattern GP (e.g., refer to FIG. 12H) in the first definition layer PD1.

According to the manufacturing method of the display panel, a process of forming the pixel definition layer PDL (e.g., refer to FIG. 4) including the organic layer and the inorganic layer stacked one on another, a process of patterning the inorganic layer, and a process of patterning the organic layer using the patterned inorganic layer as a mask are sequentially performed. Thus, the pixel definition layer PDL (e.g., refer to FIG. 4) may be precisely patterned through a simplified process.

Therefore, the differential line width structure of the pixel definition layer PDL (e.g., refer to FIG. 4) may be formed without adding a separate process.

FIG. 12H shows the structure in which the dry etching process is performed as the isotropic etching to allow the first definition layer PD1 to have the undercut shape as a representative example, however, the present disclosure should not be limited thereto or thereby. As an example, when the dry etching process is performed as the anisotropic etching, the first definition layer PD1 may not have the undercut shape.

Accordingly, the valley pattern VP may be formed in the pixel definition layer PDL. The valley pattern VP may include the groove pattern GP and the open pattern PP. The valley pattern VP may have the shape where the portion of the upper surface of the first definition layer PD1 is recessed and the portion of the upper surface of the second definition layer PD2 is penetrated. The valley pattern VP may disconnect (at least partly) the light emitting stacks ST1 to ST3 (e.g., refer to FIG. 12I) and the charge generation layers CGL1 and CGL2.

Referring to FIG. 12I, the light emitting stacks ST1 to ST3 may be formed on the second definition layer PD2, and the second electrode CE may be formed on the light emitting stacks ST1 to ST3.

FIGS. 13 to 15 are enlarged plan views of a portion of display panels DPa, DPb, and DPc according to embodiments of the present disclosure.

In FIGS. 13 to 15, the same/similar reference numerals denote the same/similar elements in FIGS. 1 to 11, and thus, detailed descriptions of the same elements may not be repeated.

Hereinafter, a structure of an open pattern (e.g., refer to PP of FIG. 7) will be described with reference to FIGS. 13 to 15.

Referring to FIG. 13, each of a first area PR1a and a second area PR2a may be defined as a single form in the display panel DPa. Accordingly, a shape of a pattern formed in a pixel definition layer (e.g., refer to PDL of FIG. 4) may be simplified.

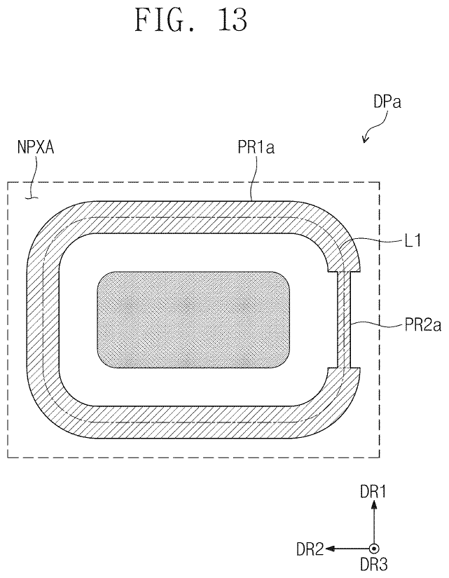

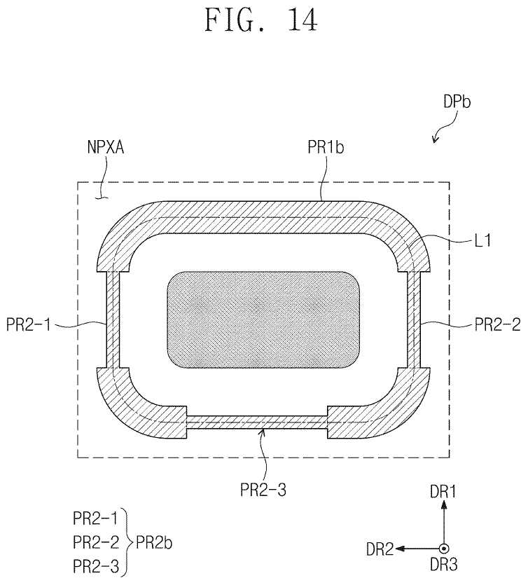

Referring to FIG. 14, the display panel DPb may include a second area PR2b that includes a second-first area PR2-1, a second-second area PR2-2, and a second-third area PR2-3 spaced apart from the second-first area PR2-1 and the second-second area PR2-2.

Therefore, the number of disconnections of light emitting stacks (e.g., refer to ST1 to ST3 of FIG. 4) and charge generation layers (e.g., refer to CGL1 and CGL2 of FIG. 4) may increase, and thus, the lateral leakage current may be effectively prevented from occurring.

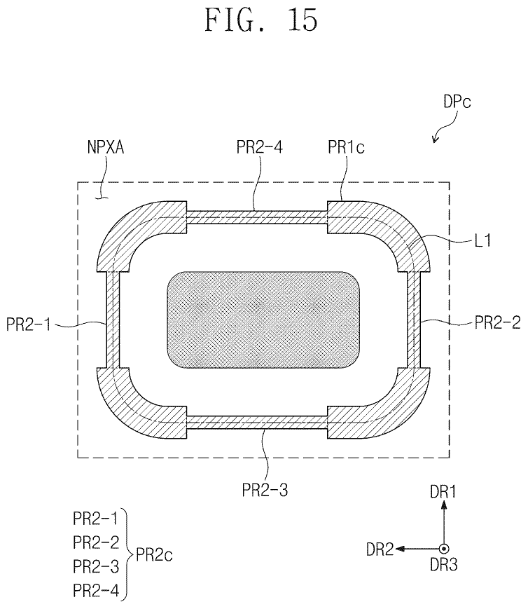

FIG. 15 is an enlarged plan view of a portion of the display panel DPc according to some embodiments of the present disclosure.

The display panel DPc may include a second area PR2c, and the second area PR2c may include a second-first area PR2-1, a second-second area PR2-2, a second-third area PR2-3, and a second-fourth area PR2-4 spaced apart from the second-first, second-second, and second-third areas PR2-1, PR2-2, and PR2-3 and facing the second-third area PR2-3 when viewed in the plane.

Therefore, the number of disconnections of light emitting stacks (e.g., refer to ST1 to ST3 of FIG. 4) and charge generation layers (e.g., refer to CGL1 and CGL2 of FIG. 4) may increase, and thus, the lateral leakage current may be effectively prevented from occurring.

Although some embodiments of the present disclosure have been described, it is understood that the present disclosure should not be limited to these embodiments but various suitable changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims and equivalents thereof.

What is claimed is:

1. A display panel comprising:
a base layer comprising pixel areas and a non-pixel area adjacent to the pixel areas;
light emitting elements each comprising a first electrode, a second electrode, and a light emitting stack between the first electrode and the second electrode and on the base layer; and
a pixel definition layer having pixel openings defined therethrough to expose at least a portion of the first electrode and opening patterns defined therein to surround the pixel openings in a plan view, each of the open patterns comprising a first area and a second area having a width different from a width of the first area.

2. The display panel of claim 1, wherein the pixel definition layer comprises:
a first definition layer having groove patterns defined therein and comprising an organic material; and
a second definition layer on the first definition layer, and having the open patterns defined therein to overlap the groove patterns, and comprising an inorganic material.

3. The display panel of claim 2, wherein the organic material comprises at least one of polyimide (PI), polystyrene (PS), or polyacrylate (PA), and the inorganic material comprises at least one of silicon (Si) or silicon nitride (SiNx).

4. The display panel of claim 2, wherein, in a plan view, a first width of the open pattern in the first area is greater than a second width of the open pattern in the second area.

5. The display panel of claim 4, wherein the first width is greater than or equal to about 0.3 micrometers and less than or equal to about 5 micrometers, and the second width is greater than or equal to about 0.05 micrometers and less than or equal to about 0.2 micrometers.

6. The display panel of claim 4, wherein the groove patterns overlapping the first area in a plan view have a first groove width greater than the first width, and the groove patterns overlapping the second area in a plan view have a second groove width greater than the second width.

7. The display panel of claim 1, wherein the second area comprises a second-first area and a second-second area spaced apart from the second-first area and facing the second-first area in a plan view.

8. The display panel of claim 7, wherein the second area further comprises a second-third area spaced apart from the second-first area and the second-second area.

9. The display panel of claim 8, wherein the second area further comprises a second-fourth area spaced apart from the second-first area, the second-second area, and the second-third area and facing the second-third area in a plan view.

10. The display panel of claim 2, wherein the open patterns completely penetrate the second definition layer from an upper surface of the second definition layer to a lower surface of the second definition layer, each of the groove patterns is recessed in a direction toward the base layer, and a maximum depth of each of the groove patterns with respect to a plane extending from the upper surface of the first definition layer is less than a height of the first definition layer.

11. The display panel of claim 2, wherein a tip portion is protruded from a side surface of the second definition layer, which defines each of the open patterns, toward a center of the open patterns and is defined in the second definition layer.

12. The display panel of claim 2, wherein the light emitting element comprises:
a first light emitting stack;
a first charge generation layer on the first light emitting stack;
a second light emitting stack on the first charge generation layer;
a second charge generation layer on the second light emitting stack; and
a third light emitting stack on the second charge generation layer.

13. The display panel of claim 12, wherein each of the first, second, and third light emitting stacks comprises a hole control layer, an electron control layer, and a light emitting layer between the hole control layer and the electron control layer, and
wherein the hole control layer comprises at least one of a hole injection layer and a hole transport layer, the hole transport layer comprises at least one of a hole buffer layer and an electron block layer, and the electron control layer comprises at least one of an electron injection layer and an electron transport layer.

14. The display panel of claim 12, wherein a pore is defined between each of the groove patterns and the light emitting stacks, at least a portion of the light emitting stacks and at least a portion of the charge generation layers are disconnected with respect to the pore to allow the pore to be positioned between disconnected portions of the light emitting stacks and the charge generation layers, and a residue comprising a same material as the light emitting stacks is in each of the groove patterns.

15. The display panel of claim 12, further comprising:
light emitting stacks on the second definition layer; and
charge generation layers between the light emitting stacks,
wherein the second electrode is on the light emitting stacks, and
wherein at least one of the light emitting stacks and the charge generation layers is disconnected in the first and second areas, and the second electrode is disconnected in an area overlapping the first area and is not disconnected in an area overlapping the second area.

16. A method of manufacturing a display panel, comprising:
providing a preliminary display panel comprising a base layer comprising pixel areas and a non-pixel area adjacent to the pixel areas, a circuit element layer on the base layer and comprising insulating layers, and a first electrode on the circuit element layer;
forming a first definition layer on the preliminary display panel;
forming pixel openings through the first definition layer;
forming a second definition layer on the first definition layer;
forming open patterns in the second definition layer;
forming groove patterns in the first definition layer to respectively overlap the open patterns;
forming light emitting stacks on the second definition layer; and
forming a second electrode on the light emitting stacks.

17. The method of claim 16, wherein each of the forming of the open patterns and the forming of the groove patterns comprises a dry etching process, and
wherein the forming of the groove patterns comprises etching an upper surface of the first definition layer toward the base layer using a light passing through the open patterns.

18. The method of claim 16, wherein the forming of the open patterns comprises forming a first portion having a first width and a second portion having a second width smaller than the first width in each of the open patterns, and
wherein the groove patterns overlapping the first portion have a first groove width greater than the first width, and the groove patterns overlapping the second portion have a second groove width greater than the second width.

19. The method of claim 16, further comprising:
forming an encapsulation layer on the second electrode the encapsulation layer comprising a first inorganic encapsulation layer, an organic encapsulation layer on the first inorganic encapsulation layer, and a second inorganic encapsulation layer on the organic encapsulation layer.

20. An electronic device comprising:
a display panel configured to display an image; and
a window on the display panel and comprising optically transparent material,
wherein the display panel comprises:
a base layer comprising pixel areas and a non-pixel area adjacent to the pixel areas;
light emitting elements each comprising a first electrode, a second electrode, and a light emitting stack between the first electrode and the second electrode and on the base layer; and
a pixel definition layer having pixel openings defined therethrough to expose at least a portion of the first electrode and opening patterns defined therein to surround the pixel openings in a plan view, each of the open patterns comprising a first area and a second area having a width different from a width of the first area.
